(19) United States
(12) Patent Application Publication
(10) Pub. No.: US 2026/0305068 A1
(43) Pub. Date: Oct. 1, 2026

(54) METHOD FOR FABRICATING DISPLAY DEVICE, DISPLAY DEVICE AND ELECTRONIC DEVICE INCLUDING THE SAME

(71) Applicant: Samsung Display Co., LTD., Yongin-si (KR)

(72) Inventors: Jin Min KIM, Yongin-si (KR); Ki Ho CHOI, Yongin-si (KR); Jung Min KIM, Yongin-si (KR); Ji Chul LEE, Yongin-si (KR); Yong CHO, Yongin-si (KR); Eun Ji CHO, Yongin-si (KR)

(21) Appl. No.: 19/440,951

(22) Filed: Jan. 6, 2026

(30) Foreign Application Priority Data
Mar. 25, 2025 (KR) 10-2025-0037822

(51) Int. Cl. H10K 59/12; H10K 71/40; H10K 59/80; H10K 59/88

(52) U.S. Cl. CPC H10K 59/1201; H10K 71/421; H10K 59/873; H10K 59/879; H10K 59/88

(57) ABSTRACT

Provided are method for fabricating display device, display device and electronic device including the same. A method for fabricating a display device, the including, forming a display layer on a substrate, irradiating laser along a first processing path onto the display layer, irradiating laser along a second processing path different from the first processing path to form a through-hole penetrating the display layer, and encapsulating the display layer on the substrate, wherein each of the first processing path and the second processing path is a spiral path.

This application claims priority to Korean Patent Application No. 10-2025-0037822, filed on Mar. 25, 2025, and all the benefits accruing therefrom under 35 U.S.C. §119, the content of which in its entirety is herein incorporated by reference.

### BACKGROUND

### Field of the Disclosure

The present disclosure relates to a method for fabricating a display device, a display device, and an electronic device including the same.

### Description of the Related Art

As the information-oriented society evolves, various demands for display devices are ever increasing. Display devices may be a liquid-crystal display device, a field emission display device, a light-emitting display device, or the like. Light-emitting display devices may include an organic light-emitting display device including organic light-emitting diodes as light-emitting elements, an inorganic light-emitting display device including inorganic light-emitting diodes as light-emitting elements, etc.

As the field of display that represents electrical signal information graphically has been rapidly grown up, a variety of display devices having excellent characteristics have been developed, which are thinner, lighter and consume less power. Recently, in order to expand the display area of a display device where images are displayed, physical buttons are removed from the front surface of the display device, and electronic elements such as a camera and a sensor are located in the display area.

In order to locate electronic elements such as a camera in the display area, a light-transmitting area is required in the display area. A camera, etc. are placed in the light-transmitting area. Therefore, the light-transmitting area needs to have excellent transmittance so as not to degrade the performance of electronic elements such as a camera.

### SUMMARY

Aspects of the present disclosure provide a method for fabricating a display device including a light-transmitting area with excellent transmittance, a display device, and an electronic device including the same.

It should be noted that aspects of the present disclosure are not limited to the above-mentioned aspect; and other aspects of the present disclosure will be apparent to those skilled in the art from the following descriptions.

According to an aspect of the present disclosure, there is provided a method for fabricating a display device. the method includes forming a display layer on a substrate, irradiating laser along a first processing path onto the display layer, irradiating laser along a second processing path different from the first processing path to form a through-hole penetrating the display layer, and encapsulating the display layer on the substrate, wherein each of the first processing path and the second processing path is a spiral path in a plan view.

In an embodiment, the first processing path and the second processing path may be spaced apart from each other.

In an embodiment, a first laser processing mark may be formed by the laser irradiated along the first processing path, a second laser processing mark may be formed by the laser irradiated along the second processing path, and the second laser processing mark may overlap at least partially with the first laser processing mark in the plan view.

In an embodiment, the second laser processing mark may be located between a first part of the first laser processing mark located on an inner turn of the spiral path and a second part of the first laser processing mark located on an outer turn of the spiral path in the plan view.

In an embodiment, the second laser processing mark may at least partially overlap with the first part of the first laser processing mark located on the inner turn of the spiral path as well as the second part of the first laser processing mark located on the outer turn of the spiral path in the plan view.

In an embodiment, each of the first laser processing mark and the second laser processing mark may include a center portion and a peripheral portion outside the center portion, and the center portion of the second laser processing mark may overlap at least partially with the center portion of the first laser processing mark in the plan view.

In an embodiment, the center portion of a part of the first laser processing mark may not overlap with the center portion of another adjacent part of the first laser processing mark in the plan view.

In an embodiment, the center portion of a part of the first laser processing mark may be spaced apart from the center portion of another adjacent part of the first laser processing mark.

In an embodiment, a width of the center portion of the second laser processing mark may be greater than a distance between centers of two adjacent parts of the first laser processing mark.

In an embodiment, the center portion of the second laser processing mark may be located between the center portion of a first part of the first laser processing mark located on an inner turn of the spiral path and the center portion of a second part of the first laser processing mark located on an outer turn of the spiral path.

In an embodiment, the center portion of the second laser processing mark at least partially may overlap with the center portion of the first part of the first laser processing mark located on the inner turn of the spiral path as well as the center portion of a second part of the first laser processing mark located on the outer turn of the spiral path in the plan view.

In an embodiment, a laser irradiation unit configured to irradiate the laser may include a light source that generates the laser, a beam expanding telescope that expands the laser generated from the light source, and an optical member that adjusts an optical path of the laser provided from the beam expanding telescope.

In an embodiment, the optical member may include a mirror that controls a direction of the optical path of the laser, a scanner that controls a position where the laser is irradiated, and an f-theta lens that controls a focus of the laser.

In an embodiment, the scanner may be configured to receive first position information regarding the first processing path and second position information regarding the second processing path from a controller.

In an embodiment, a rotation direction of the first processing path may be equal to a rotation direction of the second processing path.

In an embodiment, a rotation direction of the first processing path may be different from a rotation direction of the second processing path.

In an embodiment, the first processing path may be a spiral path that rotates from an outer side to an inner side, while the second processing path may be a spiral path that rotates from an inside to an outer side.

According to an aspect of the present disclosure, there is provided a display device including, a first area which is a light-transmitting area and a second area surrounding the first area and for displaying images, a substrate, and a display layer which is arranged on the substrate and defines therein a through-hole exposing a portion of an upper surface of the substrate in the first area, where the through-hole penetrates the display layer, and the portion of the upper surface of the substrate exposed by the through-hole includes a concave portion.

In an embodiment, a light transmittance of the concave portions may be equal to or greater than 90% of a light transmittance of another portion of the upper surface of the substrate in the second area.

According to an aspect of the present disclosure, there is provided an electronic device including, a display device, a processor configured to provide a signal to the display device, and a memory configured to store data used for operations of the processor and the display device, where the display device includes, a first area which is a light-transmitting area and a second area surrounding the first area and for displaying images, a substrate, and a display layer which is arranged on the substrate and defines therein a through-hole exposing a portion of an upper surface of the substrate in the first area, the through-hole penetrates the display layer, and the portion of the upper surface of the substrate exposed by the through-hole includes a concave portion.

According to an embodiment of the present disclosure, a display device can include a light-transmitting area with excellent transmittance.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing a display device according to an embodiment of the present disclosure.

FIG. 2 is a cross-sectional view showing an example, taken along line I –I' of FIG. 1.

FIG. 3 is a plan view showing a display device according to an embodiment of the present disclosure.

FIG. 4 is an equivalent circuit diagram of an example of a pixel of a display device according to an embodiment of the present disclosure.

FIG. 5 is a plan view showing a part of a display device according to an embodiment of the present disclosure.

FIG. 6 is a cross-sectional view showing an example, taken along line II –II' of FIG. 5.

FIG. 7 is a cross-sectional view partially showing first the fourth emission areas of the display device according to the embodiment.

FIG. 8 is an enlarged, cross-sectional view of portion A of FIG. 7.

FIG. 9 is a block diagram of an electronic device according to an embodiment of the present disclosure.

FIG. 10 is a view showing electronic devices according to a variety of embodiments of the present disclosure.

FIG. 11 is a flowchart for illustrating a method for fabricating a display device according to an embodiment of the present disclosure.

FIG. 12 is a cross-sectional view showing step S100 of FIG. 11.

FIG. 13 is a cross-sectional view showing steps S200 and S300 of FIG. 11.

FIG. 14 is a cross-sectional view showing step S400 of FIG. 11.

FIG. 15 is a plan view showing laser spots at steps S200 and S300 of FIG. 11.

FIG. 16 is a plan view showing the laser processing paths at steps S200 and S300 of FIG. 11.

FIG. 17 is a plan view showing a first laser processing mark at steps S200 and S300 of FIG. 11.

FIG. 18 is a plan view showing a second laser processing mark at steps S200 and S300 of FIG. 11.

FIG. 19 is a plan view showing a first laser processing mark and a second laser processing mark at steps S200 and S300 of FIG. 11.

FIG. 20 is an image showing a through-hole formed by a method for fabricating a display device according to Comparative Example.

FIG. 21 is an image showing a through-hole formed by a method for fabricating a display device according to an embodiment of the present disclosure.

FIG. 22 is a plan view showing a first laser processing mark in a method for fabricating a display device according to another embodiment.

FIG. 23 is a plan view showing a second laser processing mark in the method for fabricating a display device according to the embodiment.

FIG. 24 is a plan view showing a first laser processing mark and a second laser processing mark in the method for fabricating a display device according to the embodiment.

FIGS. 25-27 are plan views showing laser processing paths of a method for fabricating a display device according to embodiments.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being "on" another layer or substrate, it can be directly on the other layer or substrate, or intervening layers may also be present. The same reference numbers indicate the same components throughout the specification.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, embodiments of the present disclosure will be described in detail with reference to the accompanying drawings.

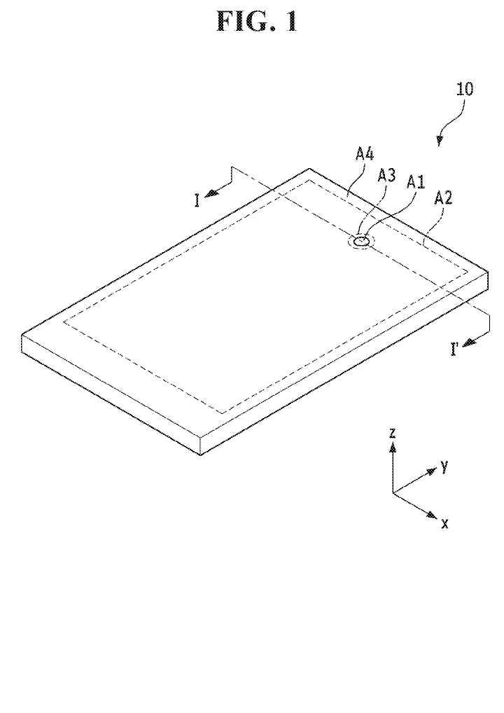

FIG. 1 is a perspective view showing a display device according to an embodiment of the present disclosure.

Referring to FIG. 1, a display device 10 may include a first area A1 and a second area A2 surrounding the first area A1.

In the first area A1, a component that can provide a variety of features to the display device 10 may be located. For example, when the component includes a sensor, a camera, etc., which use light, the first area A1 may be a light-transmitting area that allows light traveling toward the sensor or the camera to pass therethrough.

In the second area A2, a plurality of pixels, for example, an array of pixels, may be arranged. The second area A2 may display images through the array of pixels. The first area A1 may be entirely surrounded by the second area A2. Each pixel provided in the display device 10 may include a light-emitting diode as a display element capable of emitting light of a color. The light-emitting diode may include an organic light-emitting diode including an organic material as an emissive layer. Alternatively, the light-emitting diode may include an inorganic light-emitting diode. Alternatively, the light-emitting diode may include quantum dots as an emissive layer. In the following descriptions, the light-emitting diode includes an organic light-emitting diode for convenience of illustration.

A third area A3 may be located between the first area A1 and the second area A2. The third area A3 may be a non-display area where no pixels are arranged. Lines bypassing the first area A1 may be arranged in the third area A3.

A fourth area A4 surrounding the second area A2 may also be a non-display area where no pixels are arranged, like the third area A3. A variety of types of lines and built-in circuits may be arranged in the fourth area A4.

Although the first area A1 is located at the center of the second area A2 in the width direction of the display device 10 (e.g., x-axis direction) in FIG. 1, the present disclosure is not limited thereto. According to another embodiment, the first area A1 may be located closer to the left side or the right side from the center of the second area A2 in the width direction of the display device 10 (e.g., x-axis direction). In addition, the first area A1 may be located at a variety of positions in the length direction of the display device 10 (e.g., y-axis direction), such as the upper side, the center and the lower side.

In addition, although the display device 10 includes one first area A1 in the example shown in FIG. 1, the display device 10 may include a plurality of first areas A1 in some implementations.

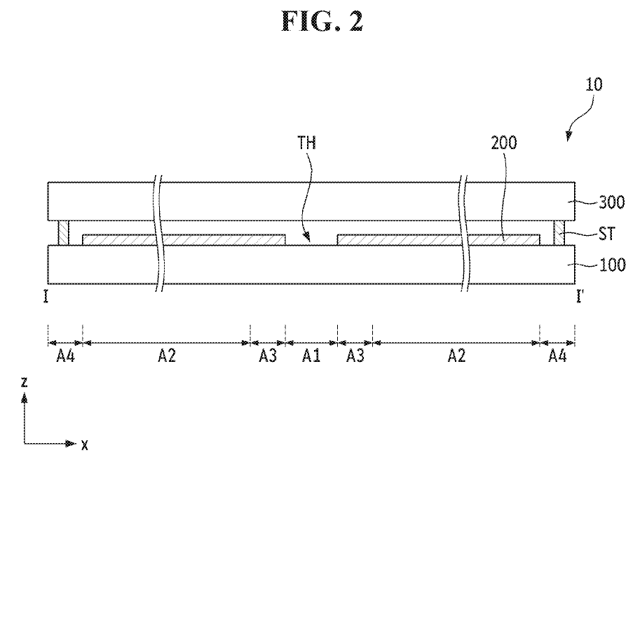

FIG. 2 is a cross-sectional view showing an example, taken along line I –I' of FIG. 1.

Referring to FIG. 2, the display device 10 includes a display layer 200 located on a substrate 100.

The substrate 100 may include a glass material or a polymer resin. For example, the substrate 100 may include a glass material having SiO₂ as a main component, or may include a resin such as a reinforced plastic.

The display layer 200 may be located in the second area A2 and may include a plurality of pixels. Each pixel included in the display layer 200 may include a pixel circuit and a display element electrically connected to the pixel circuit. The pixel circuit may include a transistor and a storage capacitor. The display element may include a light-emitting diode, e.g., an organic light-emitting diode (OLED).

The display layer 200 may be covered with an encapsulation substrate 300. The encapsulation substrate 300 may include a glass material or a polymer resin. For example, the encapsulation substrate 300 may include a glass material having SiO₂ as a main component, or may include a resin such as a reinforced plastic. The encapsulation substrate 300 may be placed such that it faces the substrate 100, and a sealant ST may be placed between the substrate 100 and the encapsulation substrate 300.

The sealant ST may be located in the fourth area A4 and may entirely surround the display layer 200 between the substrate 100 and the encapsulation substrate 300. In other words, the second area A2 may be entirely surrounded by the sealant ST when viewed from the top.

The sealant ST may be an inorganic material, for example, frit. The sealant ST may be formed by being applied using a dispenser or by screen printing. Typically, frit refers to a glass raw material in the form of powder. Herein, however, frit also includes a paste state that includes a main material such as SiO₂, along with a laser or infrared absorber, an organic binder, a filler for reducing the coefficient of thermal expansion, etc.

It should be understood, however, that the embodiments of the present disclosure are not limited thereto. The display layer 200 may be encapsulated by a thin-film encapsulation layer in which at least one inorganic encapsulation layer and at least one organic encapsulation layer are stacked.

Incidentally, the display layer 200 may define therein a through-hole TH in which at least a portion of the display layer 200 is removed. The through-hole TH may be defined as an area in which all layers that are stacked on the substrate 100 to form the display layer 200 are removed in the first area A1. The upper surface of the substrate 100 may be exposed via the through-hole TH.

Incidentally, the component may be located in line with the first area A1, and light output from the component to the outside or light traveling toward the component from the outside may pass through the first area A1, which is a light-transmitting area. For example, the component may be located at the bottom of the substrate 100, and the component may include an electronic element. Therefore, in order to avoid degradation of the performance of the component, the first area A1 is required to have excellent transmittance. To this end, it is required to prevent or suppress foreign substances such as particles and residual films, from remaining in the through-hole TH during the process of forming the through-hole TH.

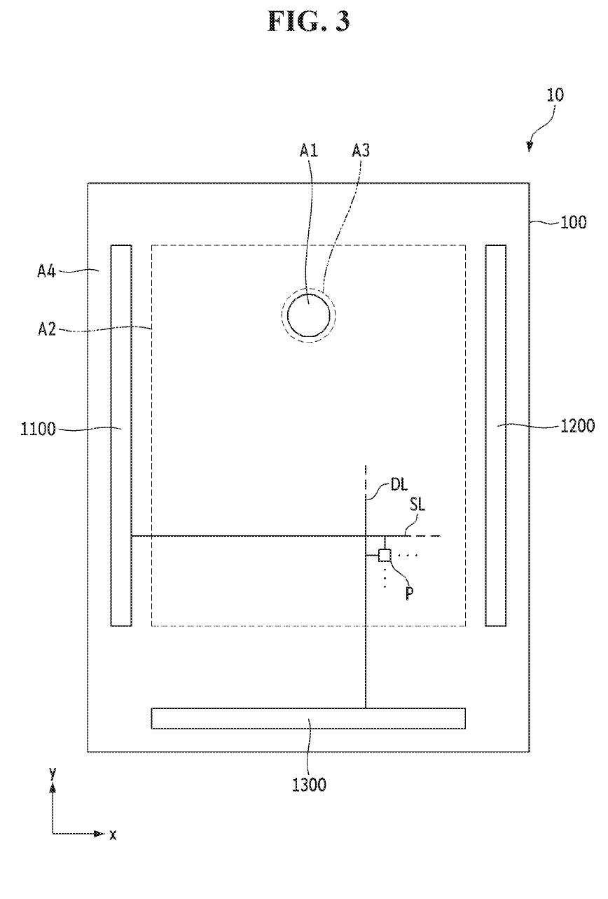

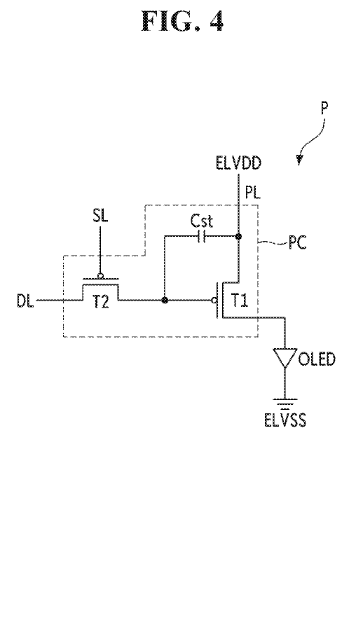

FIG. 3 is a plan view showing a display device according to an embodiment of the present disclosure. FIG. 4 is an equivalent circuit diagram of an example of a pixel of a display device according to an embodiment of the present disclosure.

Referring to FIGS. 3 and 4, a display device 10 may include a first area A1, a second area A2 surrounding the first area A1, a third area A3 between the first area A1 and the second area A2, and a fourth area A4 surrounding the second area A2.

The display device 10 may include a plurality of pixels P arranged in the second area A2. As shown in FIG. 4, each pixel P may include a pixel circuit PC, and a display element, e.g., an organic light-emitting diode OLED, connected to the pixel circuit PC. The pixel circuit PC may include a first transistor T1, a second transistor T2, and a storage capacitor Cst. Each pixel P may emit light of, e.g., red, green or blue, or may emit light of, e.g., red, green, blue or white, through the organic light-emitting diode (OLED). The first transistor T1 and the second transistor T2 may be implemented as thin-film transistors.

The first transistor T1, as a driving transistor, may be connected to a power line PL and the storage capacitor Cst, and may control a driving current flowing through the organic light-emitting diode OLED from the power line PL in response to the voltage value stored in the storage capacitor Cst. The organic light-emitting diode OLED may emit light having a luminance by the driving current. A counter electrode (e.g., a cathode electrode) of the organic light-emitting diode OLED may receive a second supply voltage ELVSS.

The second transistor T2, as a switching transistor, may be connected to a scan line SL and a data line DL, and may transmit a data voltage input from the data line DL to the first transistor T1 in response to a switching voltage input from the scan line SL.

The storage capacitor Cst may be connected to the second transistor T2 and the power line PL, and may store a voltage equal to the difference between the voltage received from the second transistor T2 and the first supply voltage ELVDD supplied to the power line PL.

Although the pixel circuit PC includes two transistors and one storage capacitor in the example shown in FIG. 4, the number of transistors and the number of storage capacitors may vary depending on the design of the pixel circuit PC in some implementations.

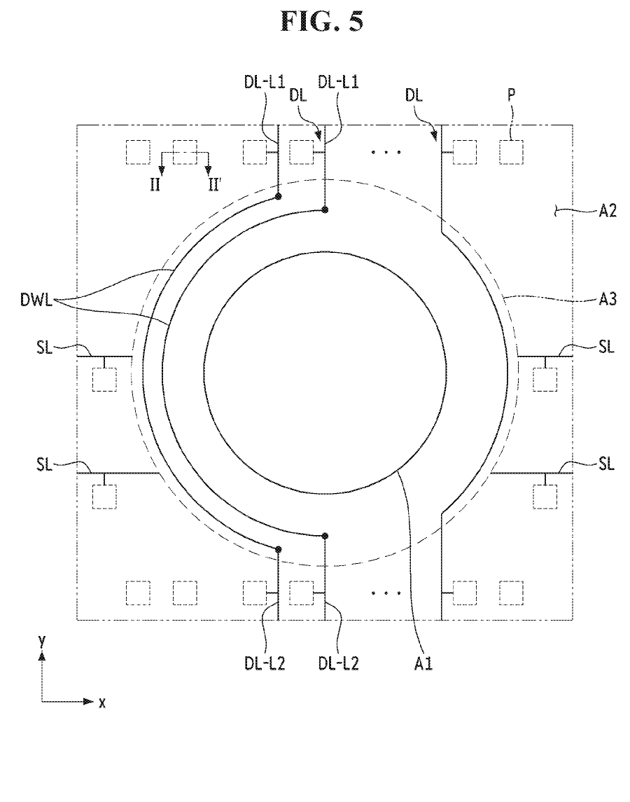

Referring back to FIG. 3, the third area A3 may surround the first area A1. The first area A1 may be a light-transmitting area through which light can pass, and the third area A3 may be an area in which no display element is arranged, such as an organic light-emitting diode that emits light. Signal lines that provide signals to pixels P around the first area A1 may pass through the third area A3. Detailed description thereon will be made below with reference to FIG. 5.

In the fourth area A4, a first scan driver 1100 that provides a scan signal to each pixel P, a second scan driver 1200, a data driver 1300 that provides a data signal to each pixel P, and a main power line (not shown) for providing a first supply voltage ELVDD and a second supply voltage ELVSS may be arranged. The first scan driver 1100 and the second scan driver 1200 may be arranged in the fourth area A4, and may be located on the opposite sides of the second area A2, respectively, with the second area A2 between the drivers 1100 and 1200.

Although the data driver 1300 is located adjacent to one side of the substrate 100 in the example shown in FIG. 3, the data driver 1300 may be located on a flexible printed circuit board (FPCB) that is electrically connected to a pad placed on one side of the display device 10 in some implementations.

FIG. 5 is a plan view showing a part of the display device according to the embodiment of the present disclosure.

Referring to FIG. 5, some of the pixels P formed in the second area A2 may be spaced apart from each other with the first area A1 at the center. For example, the first area A1 may be located between two pixels P arranged in the x-axis direction of FIG. 5. Similarly, the first area A1 may be located between two pixels P arranged in the y-axis direction of FIG. 5.

Two pixels P arranged in the y-axis direction with the first area A1 between the pixels may be electrically connected to the same data line DL, and the data line DL may bypass the first area A1 along the perimeter in the third area A3.

For example, as shown in FIG. 5, a first data line DL-L1 and a second data line DL-L2 spaced apart from each other with the first area A1 between the lines may be connected by a detour line DWL. The detour line DWL may be connected to the first data line DL-L1 and the second data line DL-L2 through contact holes. The detour line DWL may be arranged in the third area A3 such that it bypasses the first area A1.

According to another embodiment, the first data line DL-L1, the second data line DL-L2, and the detour line DWL connecting the first data line DL-L1 with the second data line DL-L2 may be formed as a single body. That is to say, the data line DL may be extended from the second area A2 and bypass the first area A1 in the third area A3.

On the other hand, two pixels P arranged in the x-axis direction with the first area A1 between the pixels may be electrically connected to different scan lines SL, respectively. Based on the drawing, the scan lines SL arranged on the left side of the first area A1 may be electrically connected to the first scan driver 1100 (see FIG. 3) described above with reference to FIG. 3, and the scan lines SL arranged on the right side of the first area A1 may be electrically connected to the second scan driver 1200 (see FIG. 3) described above with reference to FIG. 3.

According to another embodiment where the second scan driver 1200 (see FIG. 3) is eliminated, two pixels P arranged in the x-axis direction with the first area A1 between them may be connected to the same scan line. The scan line may include a bypass portion (or detour line) extended along the arc direction of the first area A1 in the third area A3, similar to the data line DL.

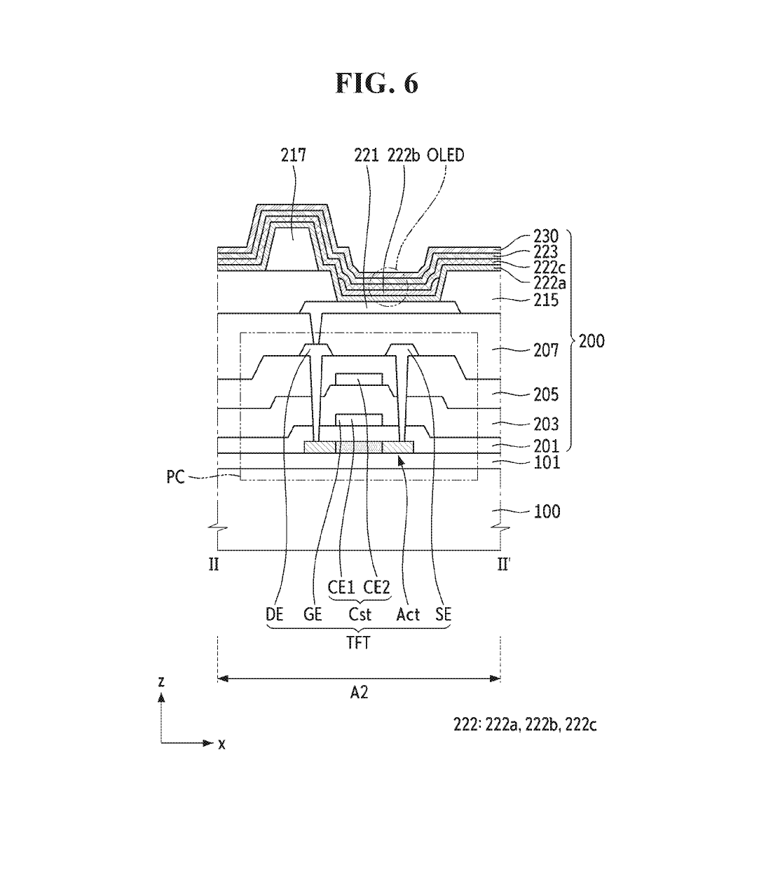

FIG. 6 is a cross-sectional view showing an example, taken along line II –II' of FIG. 5.

Referring to FIG. 6, a pixel circuit PC may be located on a substrate 100, and an organic light-emitting diode OLED electrically connected to the pixel circuit PC may be arranged on the pixel circuit PC. The substrate 100 may include glass or a polymer resin. The substrate 100 may be made up of a single layer or multiple layers.

A buffer layer 101 may be arranged on the substrate 100 to reduce or block the permeation of foreign substances, moisture, or external air from below the substrate 100, and to provide a flat surface over the substrate 100. The buffer layer 101 may include an inorganic material such as oxide and nitride, an organic material, or an organic-inorganic composite, and may have a single-layer or multi-layer structure of an inorganic material and an organic material. A barrier layer (not shown) that blocks the permeation of external air may be further included between the substrate 100 and the buffer layer 101.

The pixel circuit PC may be arranged on the buffer layer 101. The pixel circuit PC may include a thin-film transistor TFT and a storage capacitor Cst. The thin-film transistor TFT may include a semiconductor layer Act, a gate electrode GE, a source electrode SE, and a drain electrode DE. Although a top-gate thin-film transistor is shown according to the embodiment of the present disclosure, in which the gate electrode GE is located on the semiconductor layer Act with the gate insulator 201 between the gate electrode GE and the semiconductor layer Act, a bottom-gate thin-film transistor may be used as the thin-film transistor TFT according to yet another embodiment.

The semiconductor layer Act may include polysilicon. Alternatively, the semiconductor layer Act may include amorphous silicon, oxide semiconductor, organic semiconductor, etc. The gate electrode GE may include a low-resistance metal material. The gate electrode GE may include a conductive material including molybdenum (Mo), aluminum (Al), copper (Cu), titanium (Ti), etc., and may be made up of multiple layers or a single layer including the above-listed materials.

The gate insulator 201 between the semiconductor layer Act and the gate electrode GE may include an inorganic insulating material such as silicon oxide, silicon nitride, silicon oxynitride, aluminum oxide, titanium oxide, tantalum oxide, and hafnium oxide. The gate insulator 201 may be made up of a single layer or multiple layers including the above-listed materials.

The source electrode SE and the drain electrode DE may include a conductive material including molybdenum (Mo), aluminum (Al), copper (Cu), titanium (Ti), etc., and may be made up of multiple layers or a single layer including the above materials. According to an embodiment of the present disclosure, the source electrode SE and the drain electrode DE may be made up of multiple layers of Ti/Al/Ti.

The storage capacitor Cst may include a lower electrode CE1 and an upper electrode CE2 that overlap each other with a first interlayer dielectric layer 203 between the electrodes. The storage capacitor Cst may overlap with the thin-film transistor TFT. In this regard, FIG. 6 shows that the gate electrode GE of the thin-film transistor TFT is the lower electrode CE1 of the storage capacitor Cst. According to another embodiment, the storage capacitor Cst may not overlap with the thin-film transistor TFT. The storage capacitor Cst may be covered with a second interlayer dielectric layer 205.

Each of the first interlayer dielectric layer 203 and the second interlayer dielectric layer 205 may include: an inorganic insulating material such as silicon oxide, silicon nitride, silicon oxynitride, aluminum oxide, titanium oxide, tantalum oxide, and hafnium oxide. Each of the first interlayer dielectric layer 203 and the second interlayer dielectric layer 205 may be made up of a single layer or multiple layers including the above-listed materials.

The pixel circuit PC including the thin-film transistor TFT and the storage capacitor Cst may be covered with a planarization layer 207. The planarization layer 207 may include a surface having a generally flat upper surface. The planarization layer 207 may include an organic insulating material such as a general polymer such as polymethylmethacrylate (PMMA) and polystyrene (PS), a polymer derivative having a phenolic group, an acrylic polymer, an imide polymer, an aryl ether polymer, an amide polymer, a fluorine polymer, a p-xylene polymer, a vinyl alcohol polymer, and blends thereof. According to an embodiment of the present disclosure, the planarization layer 207 may include polyimide.

The pixel electrode 221 may be formed on the planarization layer 207. The pixel electrode 221 may include a conductive oxide such as indium tin oxide (ITO), indium zinc oxide (IZO), zinc oxide (ZnO), indium oxide (In₂O₃), indium gallium oxide (IGO) and aluminum zinc oxide (AZO). According to another embodiment of the present disclosure, the pixel electrode 221 may include a reflective film containing silver (Ag), magnesium (Mg), aluminum (Al), platinum (Pt), palladium (Pd), gold (Au), nickel (Ni), neodymium (Nd), iridium (Ir), chromium (Cr) or a compound thereof. According to another embodiment, the common electrode CE may further include a film made of ITO, IZO, ZnO or In₂O₃ on/under the above-described reflective film.

A pixel-defining layer 215 may be disposed on the pixel electrode 221. The pixel-defining layer 215mi includes an opening that exposes the upper surface of the pixel electrode 221, and may cover the edges of the pixel electrode 221. The pixel-defining layer 215 may include an organic insulating material. Alternatively, the pixel-defining layer 215 may include an inorganic insulating material such as silicon nitride, silicon oxynitride, and silicon oxide. Alternatively, the pixel-defining layer 215 may include an organic insulating material and an inorganic insulating material.

A spacer 217 may be formed on the pixel-defining layer 215. The spacer 217 may include an organic insulating material such as polyimide. Alternatively, the spacer 217 may include an inorganic insulating material such as silicon nitride and silicon oxide, or may include an organic insulating material and an inorganic insulating material.

According to an embodiment of the present disclosure, the spacer 217 may include a different material from the pixel-defining layer 215. Alternatively, according to another embodiment, the spacer 217 may include the same material as the pixel-defining layer 215. In this instance, the pixel-defining layer 215 and the spacer 217 may be formed together via a mask process using a halftone mask, etc. The pixel-defining layer 215 and the spacer 217 may include polyimide.

An intermediate layer 222 may include an emissive layer 222b. The emissive layer 222b may include, for example, an organic material. The emissive layer 222b may include a high molecular or low molecular weight organic material that emits light of a color. The intermediate layer 222 may include a first functional layer 222a located under the emissive layer 222b and/or a second functional layer 222c located on the emissive layer 222b.

The first functional layer 222a may be made up of a single layer or multiple layers. For example, if the first functional layer 222a is made of a polymer material, the first functional layer 222a may be made of polyethylene dihydroxythiophene (PEDOT: poly-(3,4)-ethylene-dihydroxy thiophene) or polyaniline (PANI) as a single-layer hole transport layer HTL. If the first functional layer 222a is made of a low molecular weight material, the first functional layer 222a may include a hole injection layer HIL and a hole transport layer HTL.

The second functional layer 222c may be optional. For example, if the first functional layer 222a and the emissive layer 222b are made of a polymer material, the second functional layer 222c may be formed. The second functional layer 222c may be made up of a single layer or multiple layers. The second functional layer 222c may include an electron transport layer ETL and/or an electron injection layer EIL.

The emissive layer 222b of the intermediate layer 222 may be arranged for each pixel in the second area A2. The emissive layer 222b may overlap with the opening of the pixel-defining layer 215 and/or the pixel electrode 221. Alternatively, each of the first and second functional layers 222a and 222c of the intermediate layer 222 may be formed as a single body, and may be formed not only in the second area A2 but also in the third area A3 described above with reference to FIG. 5.

The counter electrode 223 may be made of a conductive material having a low work function. For example, the counter electrode 223 may include a transparent (translucent) layer such as silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy thereof. Alternatively, the counter electrode 223 may further include a layer such as ITO, IZO, ZnO and In2O3 on the transparent (translucent) layer containing the above-described material. The counter electrode 223 may be formed as a single body to cover a plurality of pixel electrodes 211 in the second area A2.

A capping layer 230 may be located on the counter electrode 223 to improve the extraction efficiency of light emitted from an organic light-emitting diode (OLED). The capping layer 230 may include LiF, an inorganic material, or/and an organic material.

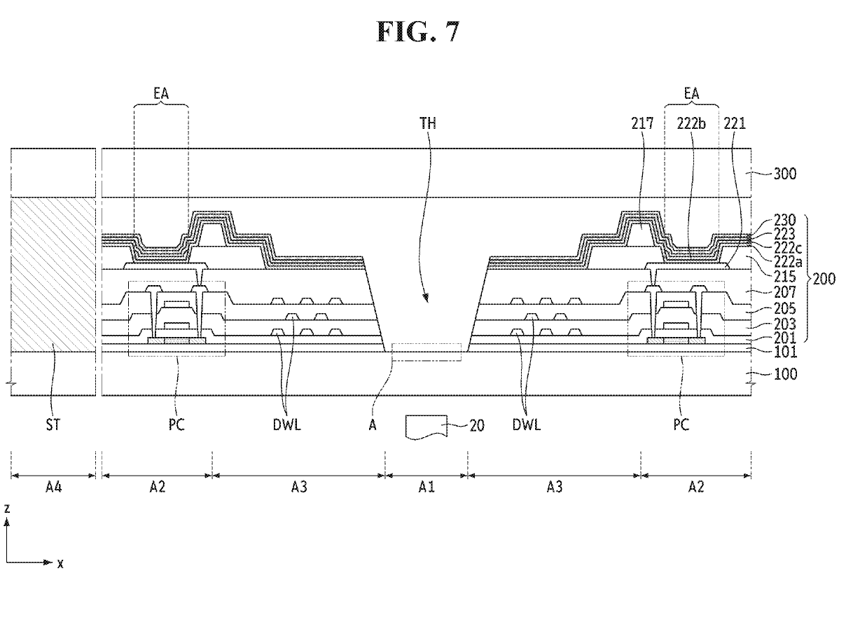

FIG. 7 is a cross-sectional view partially showing first the fourth emission areas of the display device according to the embodiment.

Referring to FIG. 7, the display layer 200 is located on the substrate 100. The display layer 200 may have a structure in which multiple layers are stacked on one another. For example, the buffer layer 101, the gate insulator 201, the first interlayer dielectric layer 203, the second interlayer dielectric layer 205, and the planarization layer 207 may be sequentially located on the substrate 100. The pixel circuit PC may include a thin-film transistor and a storage capacitor. The semiconductor layer and electrodes of the thin-film transistor and the electrodes of the storage capacitor may be respectively located on the above-described insulating layers.

The pixel electrode 221 may be located on the planarization layer 207. More specifically, the pixel electrode 221 may be located in the second area A2. The pixel electrode 221 may be connected to the thin-film transistor of the pixel circuit PC through a contact hole of the planarization layer 207.

The pixel-defining layer 215 located on the pixel electrode 221 may include an opening that overlaps the pixel electrode 221. The opening of the pixel-defining layer 215 may define an emission area EA.

The first functional layer 222a, the emissive layer 222b, the second functional layer 222c, the counter electrode 223 and the capping layer 230 may be sequentially stacked on the pixel-defining layer 215. The material and characteristics of the display layer 200 located on the substrate 100 are as described above with reference to FIG. 6.

The display layer 200 may include a through-hole TH in line with the first area A1. The through-hole TH may be formed by removing layers included in the display layer 200 described above.

More specifically, when the display layer 200 is formed, the buffer layer 101, the gate insulator 201, the first interlayer dielectric layer 203, the second interlayer dielectric layer 205, the planarization layer 207, the first functional layer 222a, the second functional layer 222c, the counter electrode 223 and the capping layer 230 formed entirely across the first area A1, the second area A2 and the third area A3 may be removed at the through-hole TH. That is to say, in the through-hole TH, the layers from the buffer layer 101 to the capping layer 230 are removed, so that no other layer is stacked on the substrate 100, and accordingly the upper surface of the substrate 100 is exposed. Accordingly, in the first area A1, the substrate 100 and the encapsulation substrate 300 may directly face each other.

According to another embodiment, the buffer layer 101, the gate insulator 201, the first interlayer dielectric layer 203, the second interlayer dielectric layer 205 and the planarization layer 207 may not be arranged in the first area A1 where the through-hole TH is to be formed in the first place. In this instance, only the first functional layer 222a, the second functional layer 222c, the counter electrode 223 and the capping layer 230 may be removed from the through-hole TH.

In some embodiments, the through-hole TH may be filled with a transparent filler to improve the structural stability of the display device 10 (see FIG. 1).

Incidentally, a component 20 may be positioned in line with the first area A1. For example, the component 20 may be placed under the substrate 100. Such a component 20 may be an electronic element that utilizes light or sound. For example, the electronic element may include a sensor that receives and utilizes light such as an infrared sensor, a camera that receives light and captures images, a sensor that outputs and detects light or sound to measure distance or recognize fingerprints, a small lamp that outputs light, or a speaker that outputs sound. For an electronic element that utilizes light, light of various wavelength ranges, such as visible light, infrared light, and ultraviolet light, may be utilized.

Therefore, if the light transmittance of the first area A1 is low, the function of the component 20 may deteriorate. To prevent this, during the process of forming the through-hole TH, it is necessary to prevent or suppress foreign substances such as particles and residual films from remaining in the through-hole TH.

The encapsulation substrate 300 may be placed to face the substrate 100 and may be bonded to each other by the sealant ST located in the fourth area A4. The encapsulation substrate 300 may include the same material and the same refractive index as the substrate 100.

On the other hand, in the third area A3, the layers stacked on the substrate 100 are not removed, and the pixel electrode 221 is not located. Accordingly, the third area A3 is a non-display area. As described above, the detour line DWL that bypasses the first area A1 may be located in the third area A3.

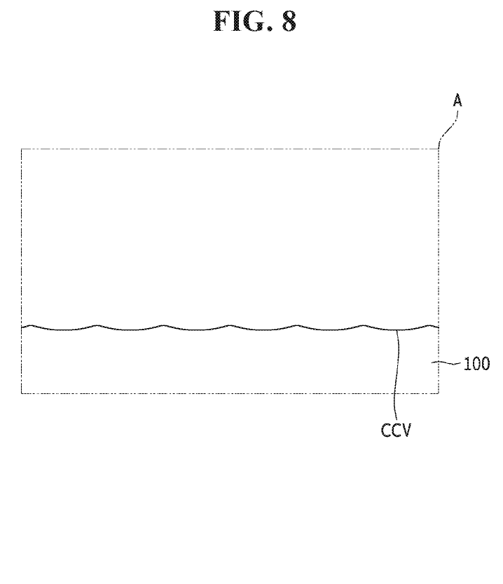

FIG. 8 is an enlarged, cross-sectional view of portion A of FIG. 7.

Referring to FIG. 8 in conjunction with FIG. 7, the substrate 100 may include a plurality of concave portions CCV located at the upper surface of the substrate 100. The plurality of concave portions CCV may have a concave shape from the upper surface toward the lower surface of the substrate 100. The plurality of concave portions CCV may be removal marks formed in the process of removing the above-described layers included in the display layer 200 to form the through-hole TH.

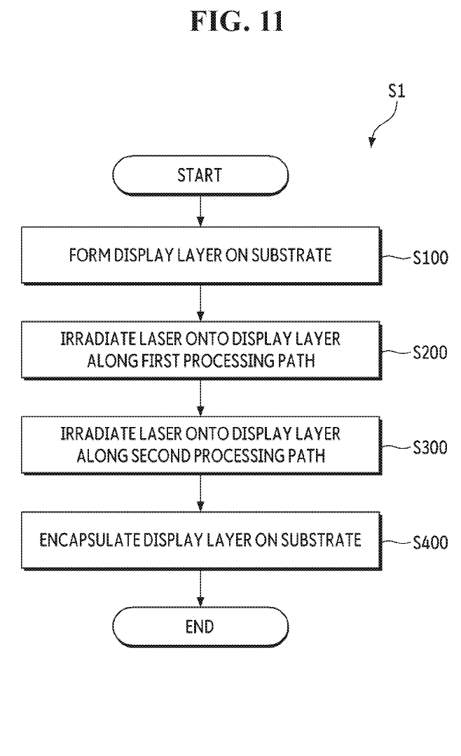

The concave portions CCV may be formed at the upper surface of the substrate 100 by the energy of the laser during the process of removing the display layer 200 by irradiating the laser in the method S1 of fabricating a display device described later (see FIG. 11).

In some embodiments, the light transmittance of the portion where the concave portions CCV are located may be substantially equal to the light transmittance of the upper surface of the substrate 100 excluding the area where the through-hole TH is formed. For example, the light transmittance of the portion where the concave portions CCV are located may be 90% to 100% of the light transmittance of the upper surface of the substrate 100 excluding the area where the through-hole TH is formed.

As used herein, the light transmittance means the transmittance for light in the visible wavelength range. For example, the visible wavelength range may be from approximately 380 nm to 780 nm.

The display device 10 according to the above-described embodiments may be applied to a variety of electronic devices 1000. The electronic device 1000 according to the embodiment may include the above-described display device 10, and may further include a module or device having additional functions in addition to the display device 10.

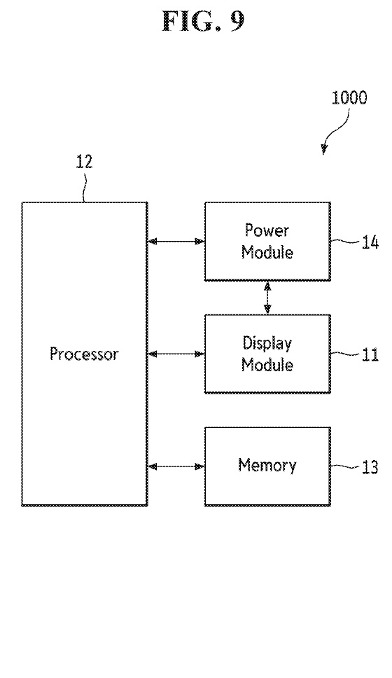

FIG. 9 is a block diagram of an electronic device according to an embodiment of the present disclosure.

Referring to FIG. 9, an electronic device 1000 according to an embodiment of the present disclosure may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and a controller.

The memory 13 may store data information required for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power required for the operation of the electronic device 1000.

At least one of the elements of the electronic device 1000 described above may be included in the display device 10 according to the embodiments described above. In addition, some of the individual modules functioning as a single module may be included in the display device 10 while some others may be provided separately from the display device 10. For example, the display device 10 may include the display module 11, and the processor 12, the memory 13 and the power module 14 may be provided as other devices inside the electronic device 1000 than the display device 10.

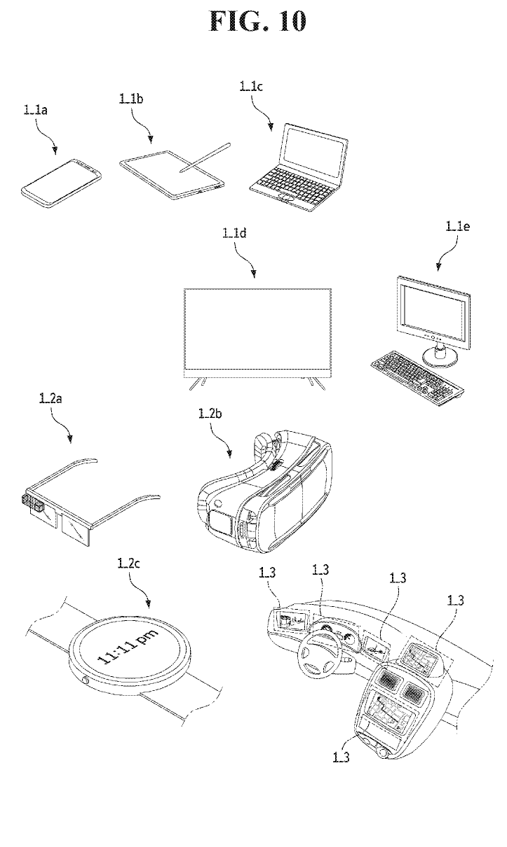

FIG. 10 is a view showing electronic devices according to a variety of embodiments of the present disclosure.

Referring to FIG. 10, a variety of electronic devices 1000 employing the display devices 10 according to the embodiments may include not only image display electronic devices such as a smart phone 1_1a, a tablet PC 1_1b, a laptop computer 1_1c, a TV 1_1d and a desktop monitor 1_1e, but also wearable electronic devices including display modules such as smart glasses 1000_2a, a head-mounted display 1_2b and a smart watch 1_2c, and electronic devices for vehicles 1_3 including display modules such as a center information display (CID) placed on the dashboard, the center fascia and the dashboard of a vehicle, and a room mirror display.

Hereinafter, a method for fabricating a display device according to an embodiment of the present disclosure will be described.

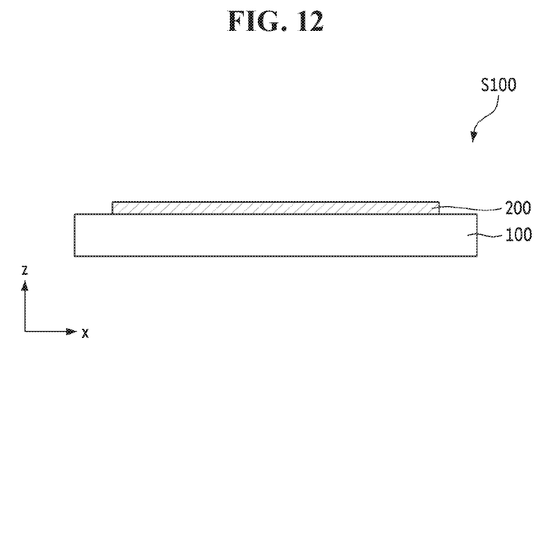

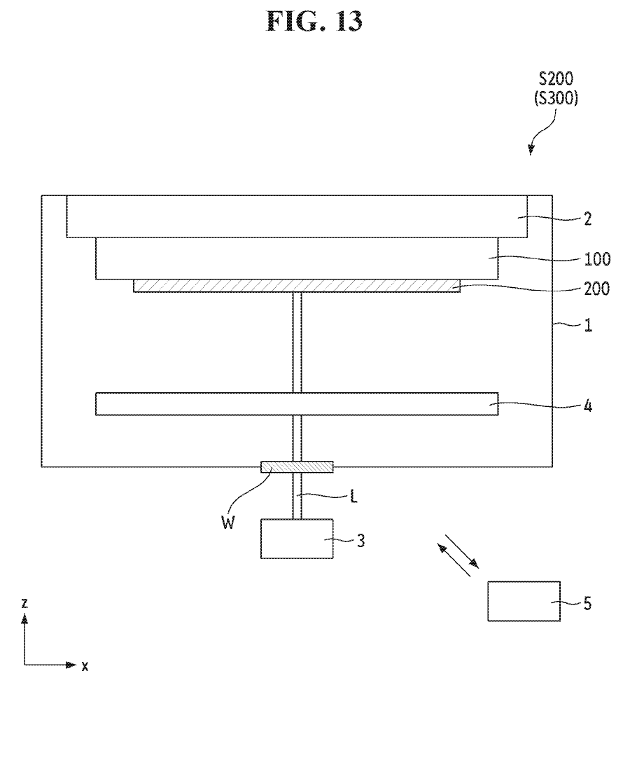

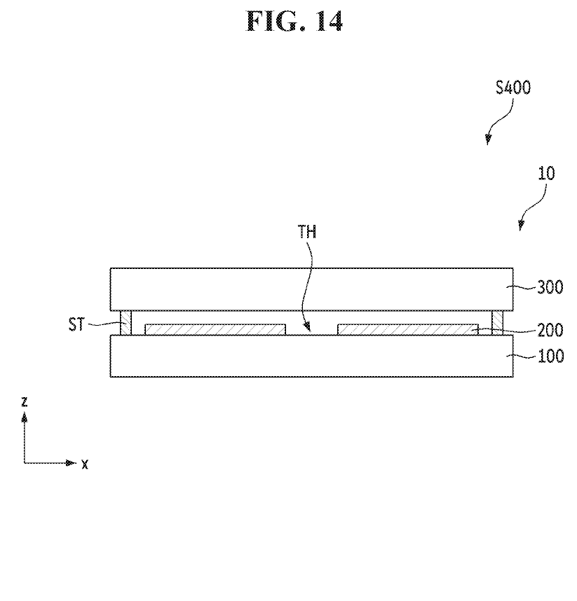

FIG. 11 is a flowchart for illustrating a method for fabricating a display device according to an embodiment of the present disclosure. FIG. 12 is a cross-sectional view showing step S100 of FIG. 11. FIG. 13 is a cross-sectional view showing steps S200 and S300 of FIG. 11. FIG. 14 is a cross-sectional view showing step S400 of FIG. 11.

Referring to FIGS. 11-14, a method S1 for fabricating a display device according to an embodiment may include: forming a display layer on a substrate (step S100); irradiating the display layer with laser along a first processing path (step S200); irradiating the display layer with laser along a second processing path (step S300); and encapsulating the display layer on the substrate (step S400).

Initially, as shown in FIG. 12, the forming the display layer on the substrate S100 may include forming the display layer 200 on the substrate 100. The substrate 100 and the display layer 200 are identical to those described above with reference to FIG. 7, etc.; and, therefore, the redundant descriptions will be omitted.

Subsequently, as shown in FIG. 13, the irradiating the display layer with the laser along the first processing path S200 and the irradiating the display layer with the laser along the second processing path S300 may include irradiating the display layer 200 with the laser L to form a through-hole TH (see FIG. 7).

After placing the substrate 100 in the chamber 1, the laser L may be irradiated onto the display layer 200 to remove a part of the display layer 200, thereby forming the through-hole TH (see FIG. 7).

The substrate 100 may be located on a carrier substrate, and the display layer 200 may be formed on the substrate 100. Then, the laser L may be irradiated to form the through-hole TH (see FIG. 7). At this time, the substrate 100 may not be removed by the irradiation of the laser L. Specifically, only a part of the display layer 200 formed on the substrate 100 may be removed by the irradiation of the laser L to form the through-hole TH, and the substrate 100 may be separated from the carrier substrate after the processes of the method S1 for fabricating a display device has been completed.

As described above with reference to FIG. 8, a plurality of concave portions CCV may be formed on the upper surface of the substrate 100 by the energy of the laser L. Such concave portions CCV may be formed along laser processing paths LP1 and LP2 described below.

The substrate 100 may be placed on an electrostatic chuck 2 in the chamber 1. For example, the substrate 100 may be fixed on the electrostatic chuck 2 so that the display layer 200 faces downward in the drawing.

For example, a laser irradiation unit 3 that irradiates the laser L may be located outside the chamber 1, and the laser L may be irradiated to the inside of the chamber 1 through a transparent window W of the chamber 1. The laser L being irradiated may be, but is not limited to, a green femtosecond laser (green fs laser).

For another example, the laser irradiation unit 3 that irradiates the laser L may be located in the chamber 1. In addition, although the laser L is directly irradiated onto the display layer 200 in the example shown in FIG. 13, the laser L may be irradiated toward the substrate 100 in some implementations, so that only a part of the display layer 200 may be removed without damaging the substrate 100 by the irradiation of the laser L.

In some embodiments, the laser irradiation unit 3 may include a light source that generates laser, a beam expanding telescope that expands laser, and optical members that adjust the optical paths of the laser (not shown). The optical members may include mirrors that extend the optical paths, a scanner that controls the position where the laser is irradiated, and an f-theta lens that controls the focus of the laser (not shown).

The chamber 1 may be maintained in a vacuum atmosphere when the laser L is irradiated so that particles generated when a part of the display layer 200 is removed by the laser L may fall. It should be understood, however, that the embodiments of the present disclosure are not limited thereto. In addition, the chamber 1 may include a baffle 4 for collecting falling particles, thereby preventing the chamber 1 from being contaminated by flying particles or particles from being attached to the display layer 200.

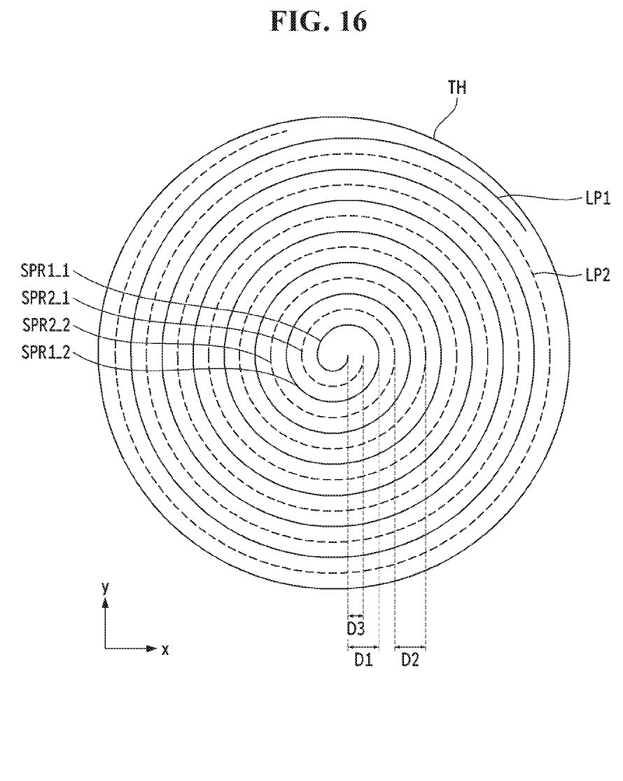

The processing process by the irradiation of the laser L may be performed at least twice, and the processing path for the irradiation of the laser L may be different for each time. For example, the processing process by the irradiation of laser L may be performed along a first processing path LP1 (see FIG. 16) and a second processing path LP2 (see FIG. 16) as described below with reference to FIG. 16.

In some embodiments, a separate controller 5 may control the laser irradiation unit 3 so that the processing process may proceed along different processing paths by the irradiation of the laser L.

For example, the controller 5 may store first position information regarding the first processing path LP1 (see FIG. 16) and second position information regarding the second processing path LP2 (see FIG. 16). The controller 5 may provide the stored first position information and second position information to the scanner of the laser irradiation unit 3 described above. The scanner of the laser irradiation unit 3 may adjust the position of the laser irradiation unit 3 so that the laser L may be irradiated along the first processing path LP1 (see FIG. 16) and the second processing path LP2 (see FIG. 16) based on the received first position information and second position information.

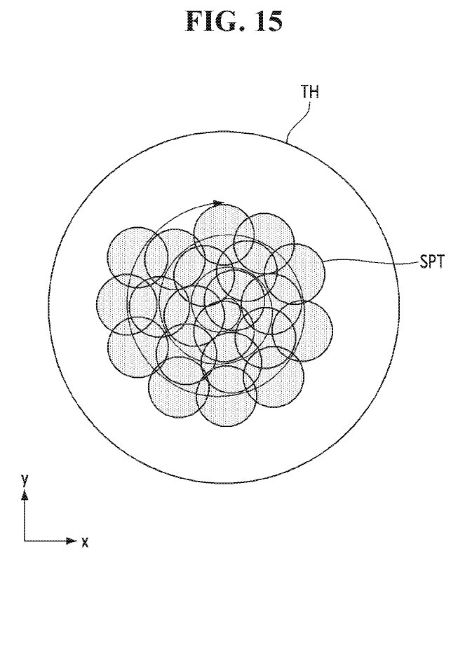

The irradiating the laser along the first processing path to the display layer S200 and the irradiating the laser along the second processing path to the display layer S300 will be described in more detail later with reference to FIG. 15, etc.

Subsequently, as shown in FIG. 14, in the encapsulating the display layer on the substrate S400, after irradiating the laser L to form the through-hole TH, the substrate 100 and the encapsulation substrate 300 may be bonded by the sealant ST.

For example, the sealant ST may be applied on the substrate 100 to surround the display layer 200, and another laser may be irradiated onto the sealant ST to cure it while the substrate 100 and the encapsulation substrate 300 come in close contact, thereby bonding the substrate 100 and the encapsulation substrate 300 together.

For another example, the display layer 200 on the substrate 100 may be encapsulated by an encapsulation film in which an inorganic encapsulation film and an organic encapsulation film are alternately stacked on one another. For example, the encapsulation film may include a first inorganic encapsulation film, an organic encapsulation film, and a second inorganic encapsulation film that are sequentially stacked on one another.

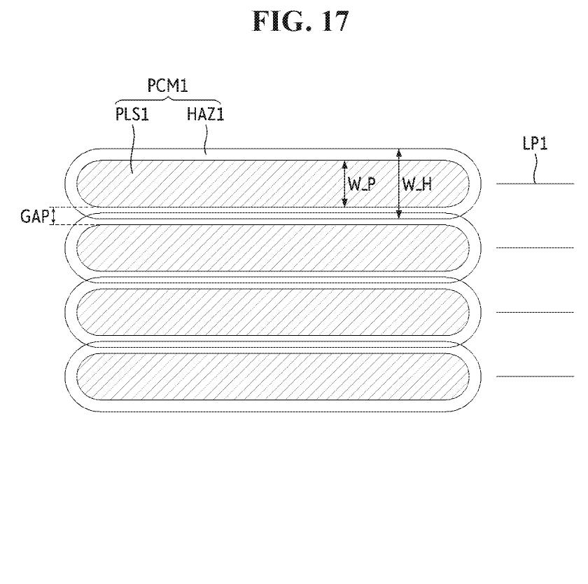

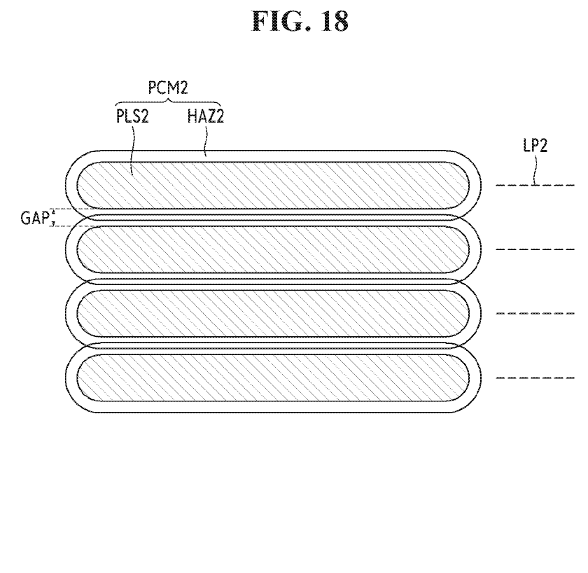

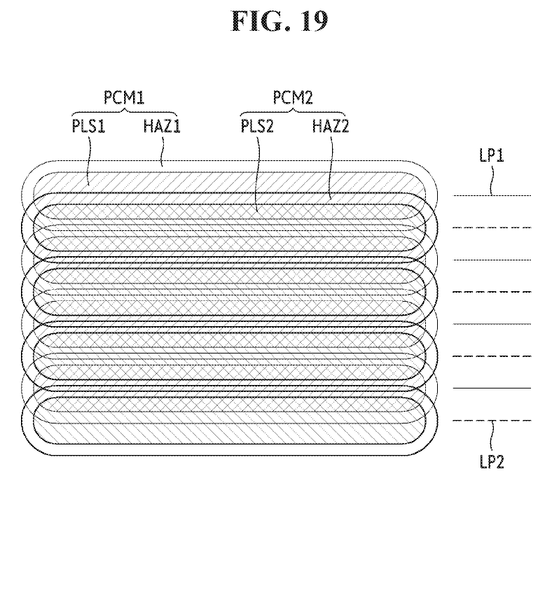

FIG. 15 is a plan view showing laser spots at steps S200 and S300 of FIG. 11. FIG. 16 is a plan view showing the laser processing paths at steps S200 and S300 of FIG. 11. FIG. 17 is a plan view showing a first laser processing mark at steps S200 and S300 of FIG. 11. FIG. 18 is a plan view showing a second laser processing mark at steps S200 and S300 of FIG. 11. FIG. 19 is a plan view showing a first laser processing mark and a second laser processing mark at steps S200 and S300 of FIG. 11. As used herein, the “plan view” is a view in a thickness direction (i.e., z-axis direction) of the substrate 100.

Referring to FIGS. 15-19, the laser L may be irradiated at least twice. For example, the laser L may be first irradiated along a first processing path LP1 (step S200), and then additionally irradiated along a second processing path LP2 (step S300).

The first processing path LP1 and the second processing path LP2 may be located at different positions. The first processing path LP1 and the second processing path LP2 may be spaced apart from each other. For example, the spiral of the second processing path LP2 and the spiral of the first processing path LP1 may be located alternately.

According to the embodiment of the present disclosure, among turns of the second processing path LP2, a first turn SPR2_1 from the center of the second processing path LP2 may be located on the outer side of a first turn SPR1_1 from the center of the first processing path LP1 among portions of the first processing path LP1, a second turn SPR1_2 from the center of the first processing path LP1 among portions of the first processing path LP1 may be located on the outer side of the first turn SPR2_1 from the center of the second processing path LP2, and a second turn SPR2_2 from the center of the second processing path LP2 among turns of the second processing path LP2 may be located on the outer side of the second turn SPR1_2 from the center of the first processing path LP1.

According another embodiment of the present disclosure, a first turn SPR1_1 from the center of the first processing path LP1 may be located on the outer side of a first turn SPR2_1 from the center of the second processing path LP2, a second turn SPR2_2 from the center of the second processing path LP2 may be located on the outer side of the first turn SPR1_1 from the center of the first processing path LP1, and a second turn SPR1_2 from the center of the first processing path LP1 may be located on the outer side of the second turn SPR2_2 from the center of the second processing path LP2.

In some embodiments, a first distance D1, which is the distance between the first turn SPR1_1 from the center of the first processing path LP1 and the second turn SPR1_2 from the center of the first processing path LP1, may range from approximately 10 micrometers (μm) to 25 μm. A second distance D2, which is the distance between the first turn SPR2_1 from the center of the second processing path LP2 and the second turn SPR2_2 from the center of the second processing path LP2, may range from approximately 10 μm to 25 μm. A third distance D3, which is the distance between the first turn SPR1_1 from the center of the first processing path LP1 and the first turn SPR2_1 from the center of the second processing path LP2, may range from approximately 5 μm to 13 μm.

The laser L may move spirally and form a through-hole TH. By irradiating the laser L spirally, it is possible to effectively prevent particles from scattering in the irradiation direction of the laser L. For example, if when laser L is irradiated straight in one of the x-axis direction and the y-axis direction and then the laser L is irradiated straight in the direction again in the next row, a discontinuous residual film pattern may be formed at the edge of a through-hole TH. In contrast, when the laser L is irradiated spirally, a smooth pattern may be formed at the edge of the through-hole TH. Accordingly, it is possible to prevent particles from being attached to other portions of the display layer 200, thereby preventing the display quality of the display device 10 from being deteriorated.

As shown in FIG. 15, the laser spots SPT may overlap each other at least partially. For example, a laser spot SPT formed earlier may at least partially overlap with a laser spot SPT formed later.

As shown in FIGS. 17 and 18, a laser spot SPT formed earlier and a laser spot SPT formed later may be connected with each other to form laser processing marks PCM1 and PCM2. The laser processing marks PCM1 and PCM2 may include a first laser processing mark PCM1 formed along the first processing path LP1, and a second laser processing mark PCM2 formed along the second processing path LP2. A path along which the center of the width of the first laser processing mark PCM1 moves may be the first processing path LP1, and a path along which the center of the width of the second laser processing mark PCM2 moves may be the second processing path LP2.

The laser processing marks PCM1 and PCM2 may include center portions PLS1 and PLS2, respectively, and peripheral portions HAZ1 and HAZ2, respectively. For example, the first laser processing mark PCM1 may include the first center portion PLS1 and the first peripheral portion HAZ1, and the second laser processing mark PCM2 may include the second center portion PLS2 and the second peripheral portion HAZ2.

The display layer 200 may be completely removed from the center portions PLS1 and PLS2, while the display layer 200 may not be completely removed from the peripheral portions HAZ1 and HAZ2. The width W_P of each of the centers PLS1 and PLS2 and the width W_H of each of the peripheral portions HAZ1 and HAZ2 may be different depending on the focusing and output of the laser L, etc. According to an embodiment of the present disclosure, the width W_P of each of the center portions PLS1 and PLS2 may be approximately 33 micrometers (µm) to 38 µm, and the width W_H of each of the peripheral portions HAZ1 and HAZ2 may be approximately 50 µm to 58 µm, but the present disclosure is not limited thereto.

In some embodiments, as shown in FIG. 15, if the size of the laser spot SPT is large enough, a laser spot SPT located in the inner spiral path and a laser spot SPT located in the outer spiral path may overlap each other at least partially. In other words, the laser processing marks PCM1 and PCM2 located in the inner spiral path may at least partially overlap with the laser processing marks PCM1 and PCM2 located in the outer spiral path.

However, in some embodiments, due to reasons such as reduced output of the laser irradiation unit 3 or optical system dispersion, the size of the laser spots SPT may become smaller, or the distance between the inner spiral path and the outer spiral path may become longer. As a result, the laser spots SPT located in the inner spiral path and the laser spots SPT located in the outer spiral path may not overlap each other.

For example, as shown in FIGS. 17 and 18, the peripheral portions HAZ1 and HAZ2 of the laser processing marks PCM1 and PCM2 may overlap each other, but the center portions PLS1 and PLS2 may not overlap each other.

In this instance, when the laser L is irradiated once along the first processing path LP1, particles and residual films may be generated in a gap GAP between the center portions PLS1 of the first laser processing mark PCM1.

According to the method S1 for fabricating a display device according to this embodiment, after the laser L is primarily irradiated along the first processing path LP1, the laser L is secondarily irradiated along the second processing path LP2, so that the center portions PLS1 of the first laser processing mark PCM1 and the center portions PLS2 of the second laser processing mark PCM2 may overlap each other, as shown in FIG. 19. That is to say, the second processing path LP2 overlaps the gap GAP between the centers PLS1 of the first laser processing marks PCM1, so that the center portion PLS2 of the second laser processing marks PCM2 can remove particles and residual films.

When the through-hole TH is formed by irradiating the laser L twice, the laser L irradiated along the first processing path LP1 may primarily remove the display layer 200. The laser L irradiated along the second processing path LP2 can remove particles and residual films remaining in the gap GAP between the center portions PLS1 of the first laser processing marks PCM1.

According to the method S1 for fabricating a display device of the embodiment, by irradiating the laser L two or more times along different paths when the through-hole TH is formed, it is possible to prevent or suppress particles remaining in the through-hole TH.

Incidentally, due to the irradiation of the laser L, the concave portions CCV described above with reference to FIG. 8 may be formed at the upper surface of the substrate 100. The concave portions CCV may be formed along the first processing path LP1 and the second processing path LP2, and may form spiral processing marks formed with the continuous concave portions CCV, such as laser processing marks PCM1 and PCM2. The spiral processing marks formed with the continuous concave portions CCV may not be generated depending on the energy level of the laser L. Even when spiral processing marks formed with the continuous concave portions CCV are generated, the light transmittance of the portion where the concave portions CCV are located may be substantially equal to the light transmittance of the upper surface of the substrate 100 excluding the area where the through-hole TH is formed, as described above,

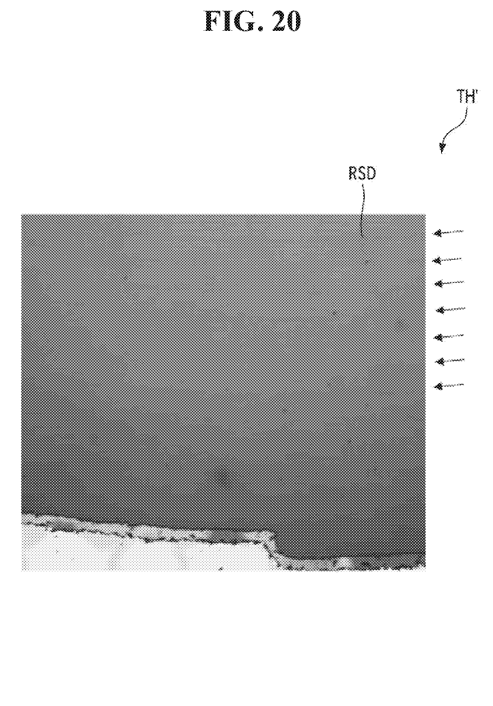

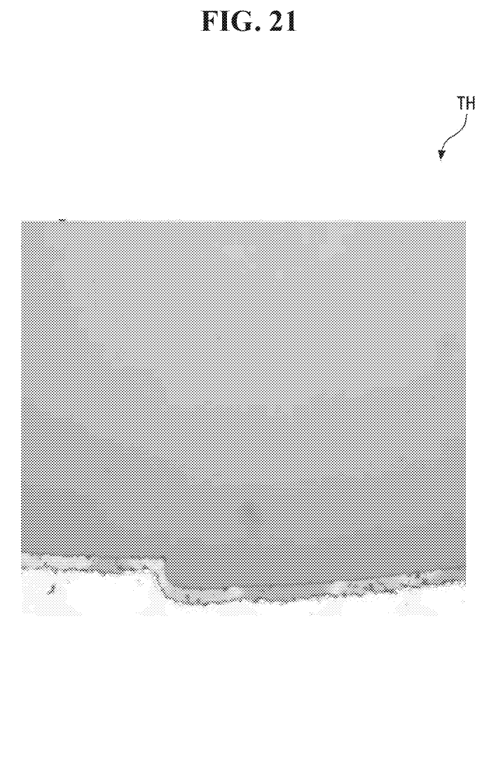

FIG. 20 is an image showing a through-hole formed by a method for fabricating a display device according to Comparative Example. FIG. 21 is an image showing a through-hole formed by a method for fabricating a display device according to an embodiment of the present disclosure.

Referring to FIGS. 20 and 21 in conjunction with FIGS. 15-19, according to the method for fabricating a display device of Comparative Example, laser L may be irradiated twice along the same path to form a through-hole TH'. In the method S1 for fabricating a display device according to the embodiment of the present disclosure, the laser L may be irradiated along different paths, for example, primarily along the first processing path LP1, and secondarily along the second processing path LP2, to form the through-hole TH, as described above.

As shown in FIG. 20, according to the method for fabricating a display device of Comparative Example, a residual film RSD (indicated by the arrows in FIG. 20) may remain on the upper surface of the substrate 100 in line with the through-hole TH'.

In contrast, according to the method S1 for fabricating a display device according to the embodiment of the present disclosure, no residual film RSD may remain on the upper surface of the substrate 100 in line with the through-hole TH or the residual film RSD can be suppressed, as shown in FIG. 21.

Hereinafter, a method for fabricating a display device according to other embodiments of the present disclosure will be described. In the following description, the same or similar elements will be denoted by the same or similar reference numerals, and redundant descriptions will be omitted or briefly described.

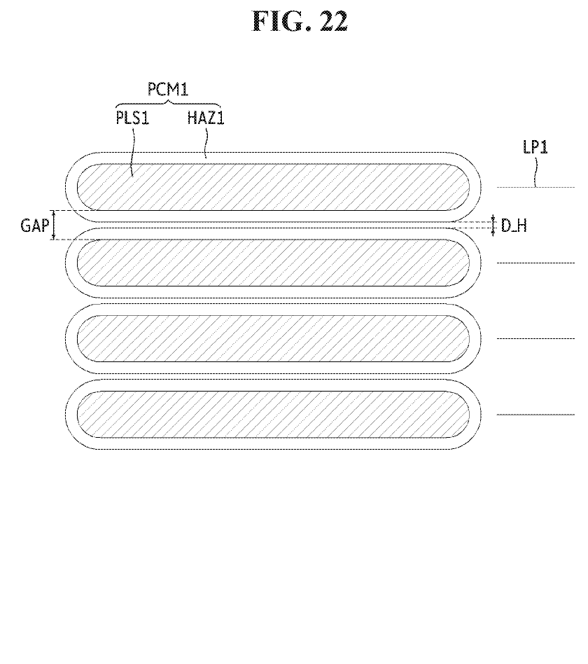

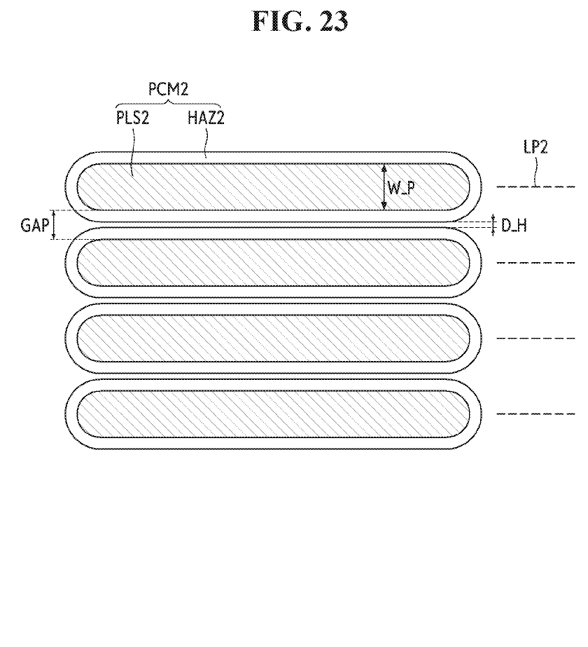

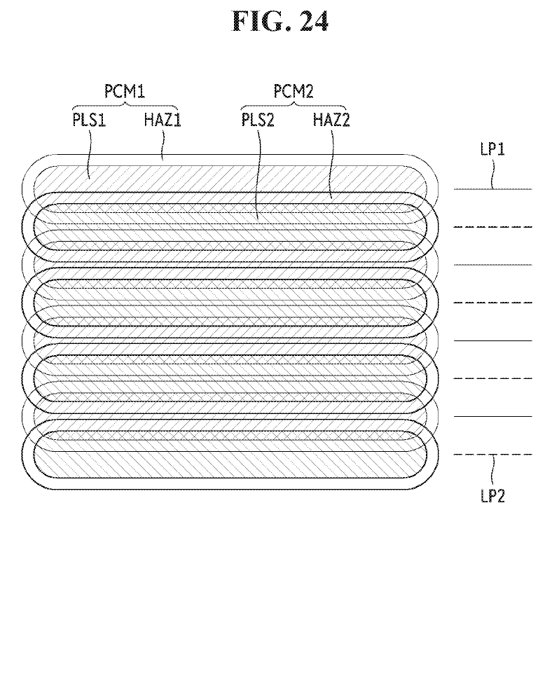

FIG. 22 is a plan view showing a first laser processing mark in a method for fabricating a display device according to another embodiment. FIG. 23 is a plan view showing a second laser processing mark in the method for fabricating a display device according to the embodiment. FIG. 24 is a plan view showing a first laser processing mark and a second laser processing mark in the method for fabricating a display device according to the embodiment.

A method S1 for fabricating a display device according to the embodiment of FIGS. 22-24 is different from the method S1 for fabricating a display device described above with reference to FIG. 17 and the like in that laser processing marks PCM1 and PCM2 are spaced apart from each other.

More specifically, due to reasons such as reduced output of the laser irradiation unit 3 or optical system dispersion, the size of the laser spots SPT may become smaller, or the distance between the inner spiral path and the outer spiral path may become longer. As a result, the laser spots SPT located in the inner spiral path and the laser spots SPT located in the outer spiral path may not overlap each other.

For example, as shown in FIGS. 22 and 23, the laser processing marks PCM1 and PCM2 may not overlap each other. The laser processing marks PCM1 and PCM2 located in the inner spiral path may be separated from the laser processing marks PCM1 and PCM2 located in the outer spiral path by a distance D_H.

When this happens, the width of the gap GAP may become larger than in the method S1 according to the embodiment described above with reference to FIG. 17, etc. When the laser L is irradiated once along the first processing path LP1, more particles and residual films may be generated in the gap GAP.

According to the method S1 for fabricating a display device according to this embodiment, after the laser L is primarily irradiated along the first processing path LP1, the laser L is secondarily irradiated along the second processing path LP2, so that the center portions PLS1 of the first laser processing mark PCM1 and the center portions PLS2 of the second laser processing mark PCM2 may overlap each other, as shown in FIG. 24. That is to say, the second processing path LP2 overlaps the gap GAP between the centers PLS1 of the first laser processing marks PCM1, so that the center portion PLS2 of the second laser processing marks PCM2 can remove particles and residual films.

In some embodiments, the gap GAP between the center portions PLS1 of the first laser processing marks PCM1 may be smaller than the width W_P of each of the center portions PLS2 of the second laser processing mark PCM2.

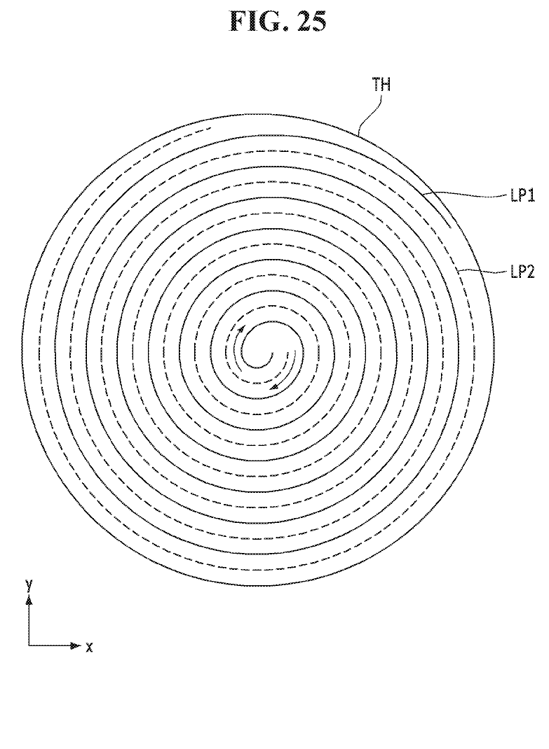

FIGS. 25-27 are plan views showing laser processing paths of a method for fabricating a display device according to embodiments.

Referring to FIGS. 25-27, the rotation direction of the laser L irradiated primarily may be different from or equal to the rotation direction of the laser L irradiated secondarily.

According to an embodiment of the present disclosure, as shown in FIG. 25, each of a first processing path LP1 and a second processing path LP2 may rotate from the center to the outer side of the spiral. In this instance, particles generated when the display layer 200 is removed may be moved to the third area A3 (see FIG. 5), which is a non-display area, thereby improving the quality of the display device 10.

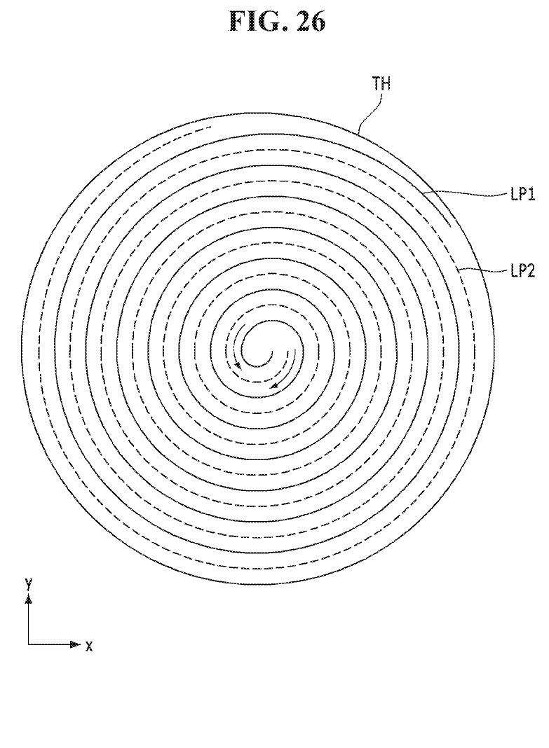

According to another embodiment of the present disclosure, as shown in FIG. 26, a first processing path LP1 may rotate from the outer side to the center of the spiral, and a second processing path LP2 may rotate from the center to the outer side of the spiral. In this instance, particles generated at the center of the spiral at the primary irradiation of the laser L may be moved to the third area A3 (see FIG. 5), which is the non-display area, at the second irradiation of the laser L, thereby improving the quality of the display device 10.

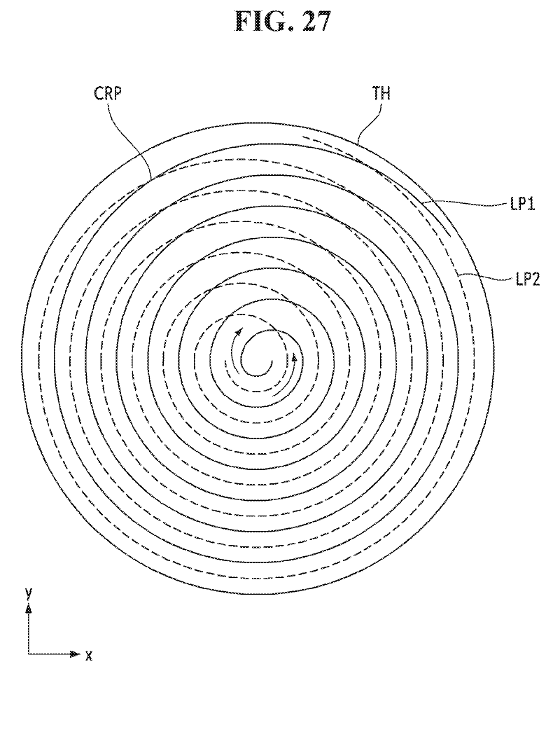

According to yet another embodiment of the present disclosure, as shown in FIG. 27, each of a first processing path LP1 and a second processing path LP2 may rotate from the center to the outer side of the spiral. It should be noted that the first processing path LP1 may rotate clockwise, while the second processing path LP2 may rotate counterclockwise. In this instance, cross portions CRP may be formed where the spiral of the first processing path LP1 and the spiral of the second processing path LP2 cross each other. Such cross points CRP may receive more energy from the laser L so that the depth of the concave portions CCV may be deeper than the other locations on the upper surface of the substrate 100. Even in this instance, the light transmittance of the portion where the concave portions CCV are located may be substantially equal to the light transmittance of the upper surface of the substrate 100 excluding the area where the through-hole TH is formed, as described above.

In concluding the detailed description, those skilled in the art will appreciate that many variations and modifications can be made to the preferred embodiments without substantially departing from the principles of the present disclosure. Therefore, the disclosed preferred embodiments of the invention are used in a generic and descriptive sense only and not for purposes of limitation.

What is claimed is:

1. A method for fabricating a display device, comprising:
forming a display layer on a substrate;
irradiating laser along a first processing path onto the display layer;
irradiating laser along a second processing path different from the first processing path to form a through-hole penetrating the display layer; and
encapsulating the display layer on the substrate,
wherein each of the first processing path and the second processing path is a spiral path in a plan view.

2. The method of claim 1, wherein the first processing path and the second processing path are spaced apart from each other.

3. The method of claim 1, wherein a first laser processing mark is formed by the laser irradiated along the first processing path, wherein a second laser processing mark is formed by the laser irradiated along the second processing path, and wherein the second laser processing mark overlaps at least partially with the first laser processing mark in the plan view.

4. The method of claim 3, wherein the second laser processing mark is located between a first part of the first laser processing mark located on an inner turn of the spiral path and a second part of the first laser processing mark located on an outer turn of the spiral path in the plan view.

5. The method of claim 4, wherein the second laser processing mark at least partially overlaps with the first part of the first laser processing mark located on the inner turn of the spiral path as well as the second part of the first laser processing mark located on the outer turn of the spiral path in the plan view.

6. The method of claim 3, wherein each of the first laser processing mark and the second laser processing mark comprises a center portion and a peripheral portion outside the center portion, and wherein the center portion of the second laser processing mark overlaps at least partially with the center portion of the first laser processing mark in the plan view.

7. The method of claim 6, wherein the center portion of a part of the first laser processing mark does not overlap with the center portion of another adjacent part of the first laser processing mark in the plan view.

8. The method of claim 6, wherein the center portion of a part of the first laser processing mark is spaced apart from the center portion of another adjacent part of the first laser processing mark.

9. The method of claim 8, wherein a width of the center portion of the second laser processing mark is greater than a distance between centers of two adjacent parts of the first laser processing mark.

10. The method of claim 6, wherein the center portion of the second laser processing mark is located between the center portion of a first part of the first laser processing mark located on an inner turn of the spiral path and the center portion of a second part of the first laser processing mark located on an outer turn of the spiral path.

11. The method of claim 10, wherein the center portion of the second laser processing mark at least partially overlaps with the center portion of the first part of the first laser processing mark located on the inner turn of the spiral path as well as the center portion of a second part of the first laser processing mark located on the outer turn of the spiral path in the plan view.

12. The method of claim 1, wherein a laser irradiation unit configured to irradiate the laser comprises:
a light source, which generates the laser;
a beam expanding telescope, which expands the laser generated from the light source; and
an optical member, which adjusts an optical path of the laser provided from the beam expanding telescope.

13. The method of claim 12, wherein the optical member comprises:
a mirror, which controls a direction of the optical path of the laser;
a scanner, which controls a position where the laser is irradiated; and
an f-theta lens, which controls a focus of the laser.

14. The method of claim 13, wherein the scanner is configured to receive first position information regarding the first processing path and second position information regarding the second processing path from a controller.

15. The method of claim 1, wherein a rotation direction of the first processing path is equal to a rotation direction of the second processing path.

16. The method of claim 1, wherein a rotation direction of the first processing path is different from a rotation direction of the second processing path.

17. The method of claim 16, wherein the first processing path is a spiral path that rotates from an outer side to an inner side, while the second processing path is a spiral path that rotates from an inside to an outer side.

18. A display device comprising:
a first area, which is a light-transmitting area, and a second area surrounding the first area and which displays images;
a substrate; and
a display layer, which is arranged on the substrate and defines therein a through-hole exposing a portion of an upper surface of the substrate in the first area,
wherein the through-hole penetrates the display layer, and
wherein the portion of the upper surface of the substrate exposed by the through-hole comprises a concave portion.

19. The display device of claim 18, wherein a light transmittance of the concave portions is equal to or greater than 90% of a light transmittance of another portion of the upper surface of the substrate in the second area.

20. An electronic device comprising:
a display device;
a processor, which provides a signal to the display device; and
a memory, which stores data used for operations of the processor and the display device,
wherein the display device comprises:
a first area, which is a light-transmitting area, and a second area surrounding the first area and which displays images;
a substrate; and
a display layer, which is arranged on the substrate and defines therein a through-hole exposing a portion of an upper surface of the substrate in the first area,
wherein the through-hole penetrates the display layer, and
wherein the portion of the upper surface of the substrate exposed by the through-hole comprises a concave portion.
